(19) United States
(12) Patent Application Publication
(10) Pub. No.: US 2023/0301139 A1
(43) Pub. Date: Sep. 21, 2023

(54) INORGANIC SILICON-CONTAINING OVERHANG STRUCTURES OF OLED SUBPIXELS

(71) Applicant: Applied Materials, Inc., Santa Clara, CA (US)

(72) Inventors: Ji Young CHOUNG, Hwaseong-si (KR); Yu-hsin LIN, Zhubei City (TW)

(21) Appl. No.: 18/006,237

(22) PCT Filed: Jun. 8, 2021
(86) PCT No.: PCT/US2021/036319

§ 371 Date: Jan. 20, 2023

Related U.S. Application Data
(60) Provisional application No. 63/075,027, filed on Sep. 4, 2020.

(51) Int. Cl. H10K 59/122; H10K 59/173; H10K 59/80; H10K 59/12; H10K 71/60

(52) U.S. Cl. CPC H10K 59/122; H10K 59/173; H10K 59/80521; H10K 59/1201; H10K 71/60

(57) ABSTRACT

The present disclosure relates to overhang structures and methods of fabricating a sub-pixel circuit with the overhang structures that may be utilized in a display such as an organic light-emitting diode (OLED) display. The adjacent inorganic silicon-containing overhang structures defining each sub-pixel of the sub- pixel circuit of the display provide for formation of the sub-pixel circuit using evaporation deposition and provide for the inorganic silicon-containing overhang structures to remain in place after the sub-pixel circuit is formed. A first configuration of the inorganic silicon-containing overhang structures includes a gradient concentration profile. A second configuration of the inorganic silicon-containing overhang structures includes an upper portion and a lower portion. The inorganic silicon-containing overhang structures define deposition angles for each of the OLED material and the cathode such the OLED material does not contact sidewalls of the inorganic silicon-containing overhang structures.

### BACKGROUND

### Field

Embodiments described herein generally relate to a display. More specifically, embodiments described herein relate to overhang structures and methods of fabricating a sub-pixel circuit 100 with the overhang structures that may be utilized in a display such as an organic light-emitting diode (OLED) display.

### Description of the Related Art

Input devices including display devices may be used in a variety of electronic systems. An organic light-emitting diode (OLED) is a light-emitting diode (LED) in which the emissive electroluminescent layer is a film of an organic compound that emits light in response to an electric current. OLED devices are classified as bottom emission devices if light emitted passes through the transparent or semi-transparent bottom electrode and substrate on which the panel was manufactured. Top emission devices are classified based on whether or not the light emitted from the OLED device exits through the lid that is added following the fabrication of the device. OLEDs are used to create display devices in many electronics today. Today's electronics manufacturers are pushing these display devices to shrink in size while providing higher resolution than just a few years ago.

OLED pixel patterning is currently based on a process that restricts panel size, pixel resolution, and substrate size. Rather than utilizing a fine metal mask, photo lithography should be used to pattern pixels. Currently, OLED pixel patterning requires lifting off organic material after the patterning process. When lifted off, the organic material leaves behind a particle issue that disrupts OLED performance. Accordingly, what is needed in the art are sub-pixel circuits and methods of forming sub-pixel circuits to increase pixel-per-inch and provide improved OLED performance.

### SUMMARY

In one embodiment, a device is provided. The device includes a substrate and adjacent pixel-defining layer (PDL) structures disposed over the substrate that define sub-pixels of the device. The device further includes inorganic silicon- containing overhang structures disposed over an upper surface of the PDL structures. The inorganic silicon-containing overhang structures include an oxygen concentration and a nitrogen concentration, wherein at least one of the oxygen concentration decreases or the nitrogen concentration increases from the upper surface of the PDL structures or at least one of the oxygen concentration increases or the nitrogen concentration decreases from the upper surface of the PDL structures. The device further includes a plurality of sub-pixels. Each sub-pixel includes an anode and an organic light-emitting diode (OLED) material disposed over and in contact with the anode. The plurality of sub-pixels further includes a cathode disposed over the OLED material, wherein the inorganic silicon-containing overhang structures disposed over the upper surface of the PDL structure extend over a portion of the OLED material and the cathode.

In another embodiment, a device is provided. The device includes a substrate and adjacent pixel-defining layer (PDL) structures disposed over the substrate that define sub-pixels of the device. The device further includes inorganic silicon-containing overhang structures disposed over an upper surface of the PDL structures. The inorganic silicon-containing overhang structures include a lower portion. The lower portion includes a first composition of at least one of a silicon oxide, a silicon nitride, or a silicon oxy-nitride and an upper portion is disposed on the lower portion. The upper portion includes an underside edge extending past a sidewall of the lower portion. The upper portion is at least one of the silicon oxide, the silicon nitride, or the silicon oxy-nitride, wherein the lower portion and the upper portion are different. The device further includes a plurality of sub-pixels. Each sub-pixel includes an anode and an organic light-emitting diode (OLED) material disposed over and in contact with the anode. The plurality of sub-pixels further includes a cathode disposed over the OLED material, wherein the inorganic silicon-containing overhang structures disposed over the upper surface of the PDL structure extend over a portion of the OLED material and the cathode.

In yet another embodiment, a device is provided. The device includes a plurality of sub-pixels, each sub-pixel of the plurality of sub-pixels is defined by adjacent pixel-defining layer (PDL) structures with inorganic silicon-containing overhang structures disposed on the PDL structures. Each sub-pixel includes an anode, an organic light-emitting diode (OLED) material disposed on the anode, and a cathode disposed on the OLED material. The device is made by a process including the steps of disposing a silicon-containing layer over an upper surface of the PDL structures. The silicon-containing layer includes an oxygen concentration and a nitrogen concentration, wherein at least one of the oxygen concentration decreases or the nitrogen concentration increases from the upper surface of the PDL structures or at least one of the oxygen concentration increases or the nitrogen concentration decreases from the upper surface of the PDL structures. The process further includes disposing a resist layer over the silicon-containing layer and patterning the resist layer to form pixel openings in the resist layer. The process further includes etching the silicon-containing layer exposed by the pixel openings to form the inorganic silicon-containing overhang structures and depositing the OLED material and the cathode using evaporation deposition.

In yet another embodiment, a device is provided. The device includes a plurality of sub-pixels, each sub-pixel of the plurality of sub-pixels defined by adjacent pixel-defining layer (PDL) structures with inorganic silicon-containing overhang structures disposed on the PDL structures. Each sub-pixel includes an anode, an organic light-emitting diode (OLED) material disposed on the anode, and a cathode disposed on the OLED material. The device is made by a process including the steps of disposing a lower portion layer and an upper portion layer over an upper surface of the PDL structures. The lower portion layer includes at least one of a silicon oxide, a silicon nitride, or a silicon oxy-nitride. The upper portion layer includes at least one of the silicon oxide, the silicon nitride, or the silicon oxy-nitride, wherein the lower portion layer and the upper portion layer are different. The process further includes disposing a resist layer over the upper portion layer and patterning the resist layer to form pixel openings in the resist layer. The process further includes etching the upper portion layer and the lower portion layer exposed by the pixel openings to form the inorganic silicon-containing overhang structures and depositing the OLED material and the cathode using evaporation deposition.

In yet another embodiment, a method is provided. The method includes disposing a silicon-containing layer over adjacent pixel defining layer (PDL) structures, each sub-pixel of a plurality of sub-pixels defined by the adjacent PDL structures. The silicon-containing layer includes an oxygen concentration and a nitrogen concentration, wherein the oxygen concentration decreases and the nitrogen concentration increases from an upper surface of the PDL structures or the oxygen concentration increases and the nitrogen concentration decreases from the upper surface of the PDL structures. The method includes disposing a resist layer over the silicon-containing layer and patterning the resist layer to form pixel openings in the resist layer and etching the silicon-containing layer exposed by the pixel openings to form inorganic silicon-containing overhang structures. The method further includes depositing an organic light-emitting diode (OLED) material and a cathode using evaporation deposition.

In yet another embodiment a method is provided. The method includes disposing a lower portion layer and an upper portion layer over adjacent pixel defining layer (PDL) structures, each sub-pixel of a plurality of sub-pixels defined by the adjacent PDL structures. The lower portion layer includes at least one of a silicon oxide, a silicon nitride, or a silicon oxy-nitride. The upper portion layer includes at least one of the silicon oxide, the silicon nitride, or the silicon oxy-nitride, wherein the lower portion layer and the upper portion layer are different. The method further includes disposing a resist layer over the upper portion layer and patterning the resist layer to form pixel openings in the resist layer and etching the upper portion layer and the lower portion layer exposed by the pixel openings to form inorganic silicon-containing overhang structures. The method further includes depositing an organic light-emitting diode (OLED) material and a cathode using evaporation deposition.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, and may admit to other equally effective embodiments.

FIGS. 1A and 1B are schematic, cross-sectional views of a sub-pixel circuit having a plug arrangement according to embodiments.

FIGS. 1C and 1D are schematic, cross-sectional views of a sub-pixel circuit having a plugless arrangement according to embodiments.

FIG. 1E is a schematic, top sectional view of a sub-pixel circuit having a dot-type architecture according to embodiments.

FIG. 1F is a schematic, cross-sectional view of a sub-pixel circuit having a line-type architecture according to embodiments.

FIG. 2A and FIG. 2B are schematic, cross-sectional views of an inorganic silicon-containing overhang structure according to embodiments.

FIG. 3 is a flow diagram of a method for fabricating a sub-pixel circuit with inorganic silicon-containing overhang structures having a gradient concentration profile according to embodiments.

FIGS. 4A-4D are schematic, cross-sectional views of a substrate during a method for forming the sub-pixel circuit according embodiments.

FIG. 5 is a flow diagram of a method for fabricating a sub-pixel circuit 100 with inorganic silicon-containing overhang structures including an upper portion and a lower portion according to embodiments.

FIGS. 6A-6D are schematic, cross-sectional views of a substrate during a method for forming the sub-pixel circuit according embodiments.

To facilitate understanding, identical reference numerals have been used, where possible, to designate identical elements that are common to the figures. It is contemplated that elements disclosed in one embodiment may be beneficially utilized on other embodiments without specific recitation.

### DETAILED DESCRIPTION

Embodiments described herein generally relate to a display. More specifically, embodiments described herein relate to overhang structures and methods of fabricating a sub-pixel circuit 100 with the overhang structures that may be utilized in a display such as an organic light-emitting diode (OLED) display. In one embodiment, which can be combined with other embodiments described herein, the display is a bottom emission (BE) or a top emission (TE) OLED display. In another embodiment, which can be combined with other embodiments described herein, the display is a passive-matrix (PM) or an active matrix (AM) OLED display.

A first exemplary embodiment of the embodiments described herein includes a sub-pixel circuit having a dot-type architecture. A second exemplary embodiment of the embodiments described herein includes a sub-pixel circuit having a line-type architecture. A third exemplary embodiment of the embodiments described herein includes a sub-pixel circuit having a dot-type architecture with a plug disposed on an encapsulation layer of a respective sub-pixel. A fourth exemplary embodiment of the embodiments described herein includes a sub-pixel circuit having a line-type architecture with a plug disposed on an encapsulation layer of a respective sub-pixel. A fifth exemplary embodiment of the embodiments described herein includes a method to fabricate inorganic silicon-containing overhang structures having a gradient concentration profile of one of the first, second, third, or fourth exemplary embodiments. A sixth exemplary embodiment of the embodiments described herein includes a method to fabricate inorganic silicon-containing overhang structures with an upper portion and a lower portion of one of the first, second, third, or fourth exemplary embodiments.

Each of the embodiments (including the first-sixth exemplary embodiments) described herein of the sub-pixel circuit include a plurality of sub-pixels with each of the sub-pixels defined by adjacent inorganic silicon-containing overhang structures that are permanent to the sub-pixel circuit. While the Figures depict two sub-pixels with each sub-pixel defined by adjacent inorganic silicon-containing overhang structures, the sub-pixel circuit of the embodiments described herein includes a plurality of sub-pixels, such as two or more sub-pixels. Each sub-pixel has the OLED material configured to emit a white, red, green, blue or other color light when energized. E.g., the OLED material of a first sub-pixel emits a red light when energized, the OLED material of a second sub-pixel emits a green light when energized, and the OLED material of a third sub-pixel emits a blue light when energized.

The inorganic silicon-containing overhang structures are permanent to the sub-pixel circuit. A first configuration of the inorganic silicon-containing overhang structures includes a gradient concentration profile. A second configuration of the inorganic silicon-containing overhang structures includes an upper portion and a lower portion. A third configuration of the inorganic silicon-containing overhang structures including the layer of inorganic materials having the gradient concentration profile includes an assistant cathode disposed under the inorganic silicon-containing overhang structures. A fourth configuration of the inorganic silicon-containing overhang structures includes the upper portion of the upper portion layer, the lower portion of the lower portion layer, and an assistant cathode disposed under the lower portion. Any of the first, second, third, and fourth exemplary embodiments include inorganic silicon-containing overhang structures of at least one of the first, second, third, or fourth configurations.

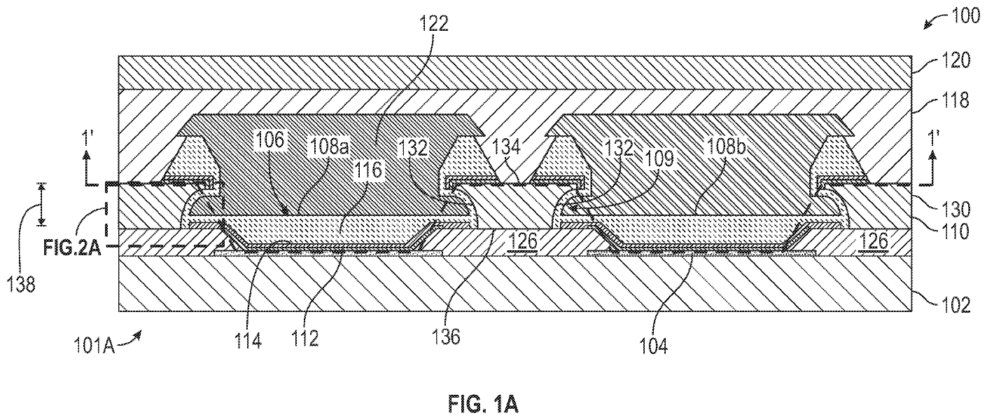

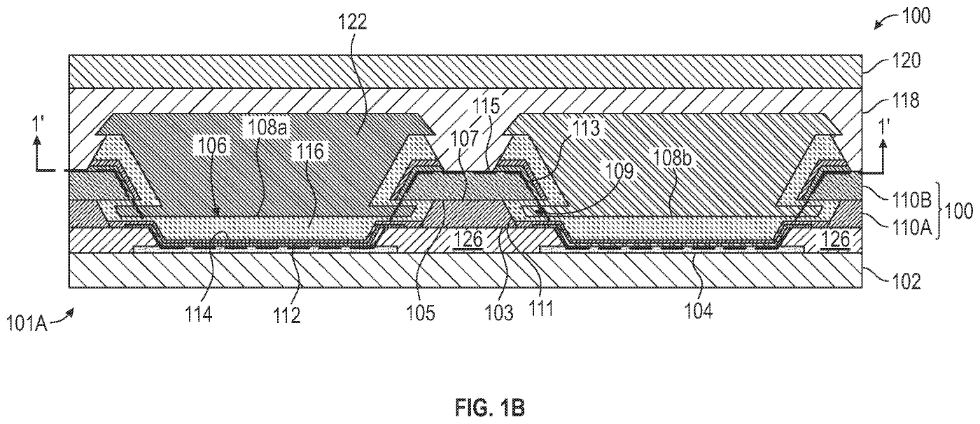

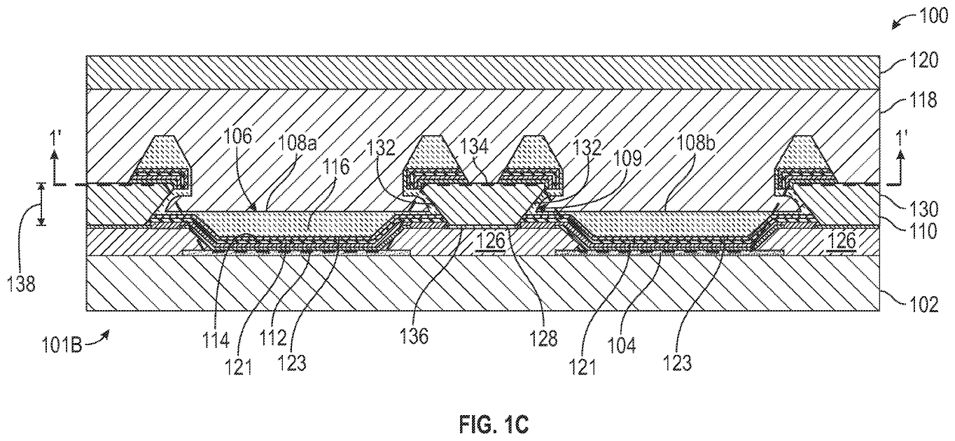

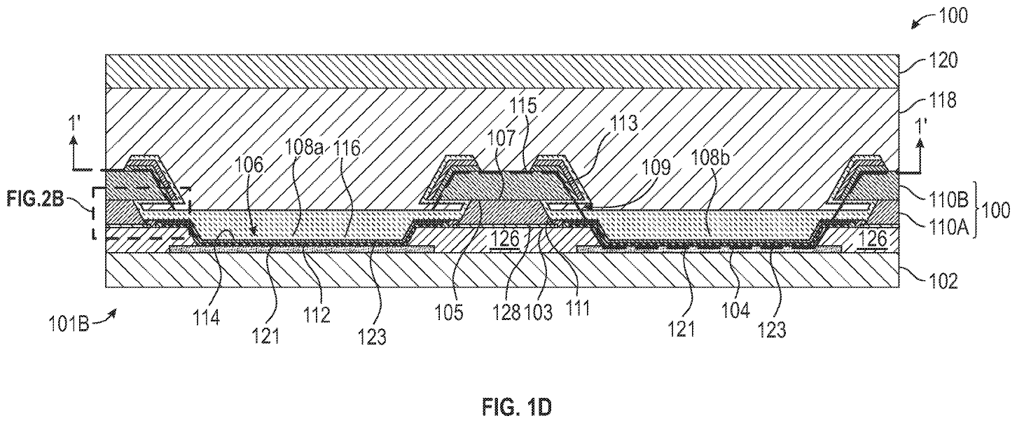

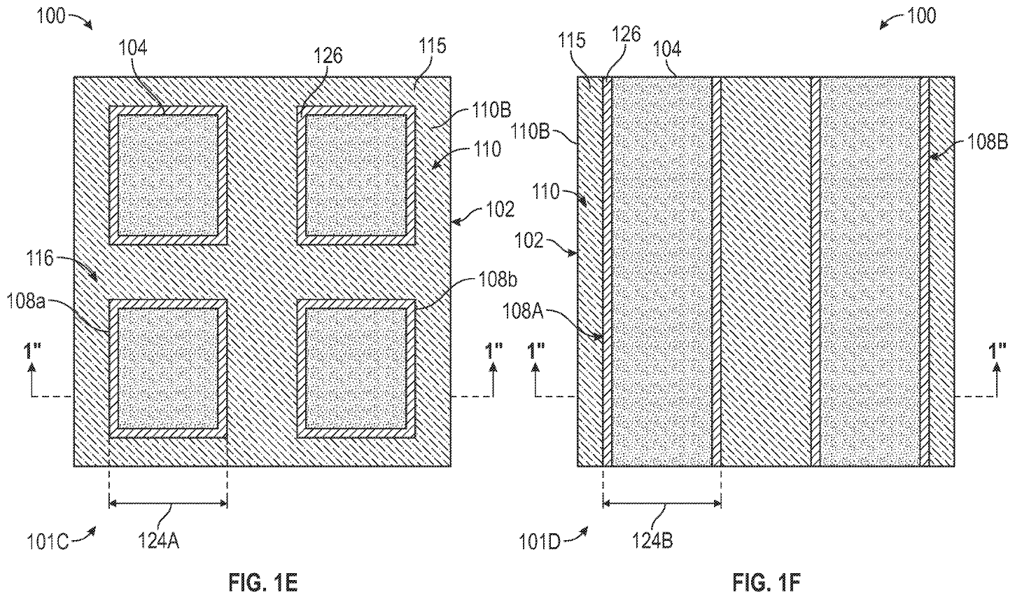

The adjacent inorganic silicon-containing overhang structures defining each sub-pixel of the sub-pixel circuit of the display provide for formation of the sub-pixel circuit using evaporation deposition and provide for the inorganic silicon-containing overhang structures to remain in place after the sub-pixel circuit is formed. Evaporation deposition may be utilized for deposition of an OLED material (including a hole injection layer (HIL), a hole transport layer (HTL), an emissive layer (EML), and an electron transport layer (ETL)) and cathode. One or more of an encapsulation layer, the plug, and a global passivation layer may be disposed via evaporation deposition. In embodiments including one or more capping layers, the capping layers are disposed between the cathode and the encapsulation layer. The inorganic silicon-containing overhang structures define deposition angles, i.e., provide for a shadowing effect during evaporation deposition, for each of the OLED material and the cathode such the OLED material. The inorganic silicon-containing overhang structures define the deposition angles for the OLED material such that the OLED material does not contact the inorganic silicon-containing overhang structures (and assistant cathode according to embodiments with the third and fourth configurations). In some embodiments, which can be combined with other embodiments described herein, e.g., as shown in FIG. 1A, the cathode does not contact the inorganic silicon-containing overhang structures (and assistant cathode according to embodiments with the third and fourth configurations). In other embodiments, which can be combined with other embodiments described herein, e.g., as shown in FIG. 1B, the cathode contacts the inorganic silicon-containing overhang structures. In other embodiments, which can be combined with other embodiments described herein, e.g., as shown in FIGS. 1C and 1D, the cathode contacts at least the assistant cathode and may contact the inorganic silicon-containing overhang structures.

The encapsulation layer of a respective sub-pixel is disposed over the cathode with the encapsulation layer extending under at least a portion of each of the adjacent inorganic silicon-containing overhang structures and along a sidewall of each of the adjacent inorganic silicon-containing overhang structures.

FIGS. 1A and 1B are schematic, cross-sectional views of a sub-pixel circuit 100 having a plug arrangement 101A. The plug arrangement 101A may correspond to the third or fourth exemplary embodiments of the sub-pixel circuit 100. The sub-pixel circuit 100 of FIG. 1A includes a first configuration of inorganic silicon-containing overhang structures 110 having a gradient concentration profile. The sub-pixel circuit 100 of FIG. 1B includes a second configuration of the inorganic silicon-containing overhang structures 110 with an upper portion and a lower portion.

FIGS. 1C and 1D are schematic, cross-sectional views of a sub-pixel circuit 100A having a plugless arrangement 101B. The plugless arrangement 101B may correspond to the first or second exemplary embodiments of the sub-pixel circuit 100. The sub-pixel circuit 100 of FIG. 1C includes a third configuration of the inorganic silicon-containing overhang structures 110 having the gradient concentration profile and an assistant cathode 128 disposed under the inorganic silicon-containing overhang structures 110. The sub-pixel circuit 100 of FIG. 1D includes a fourth configuration of the inorganic silicon-containing overhang structures 110 with the upper portion, the lower portion, and an assistant cathode 128 disposed under the lower portion.

The sub-pixel circuit 100 includes a substrate 102. Metal layers 104 may be patterned on the substrate 102 and are defined by adjacent pixel-defining layer (PDL) structures 126 disposed on the substrate 102. In one embodiment, which can be combined other embodiments described herein, the metal layers 104 are pre-patterned on the substrate 102. E.g., the substrate 102 is a pre-patterned indium tin oxide (ITO) glass substrate. The metal layers 104 are configured to operate anodes of respective sub-pixels. The metal layers 104 include, but are not limited to, chromium, titanium, gold, silver, copper, aluminum, ITO, a combination thereof, or other suitably conductive materials.

The PDL structures 126 are disposed on the substrate 102. The PDL structures 126 include one of an organic material, an organic material with an inorganic coating disposed thereover, or an inorganic material. The organic material of the PDL structures 126 includes, but is not limited to, polyimides. The inorganic material of the PDL structures 126 includes, but is not limited to, silicon oxide (SiO₂), silicon nitride (Si₃N₄), silicon oxynitride (Si₂N₂O), magnesium fluoride (MgF₂), or combinations thereof. Adjacent PDL structures 126 define a respective sub-pixel and expose the anode (i.e., metal layer 104) of the respective sub-pixel of the sub-pixel circuit 100.

The sub-pixel circuit 100 has a plurality of sub-pixels 106 including at least a first sub-pixel 108a and a second sub-pixel 108b. While the Figures depict the first sub-pixel 108a and the second sub-pixel 108b. The sub-pixel circuit 100 of the embodiments described herein may include two or more sub-pixels 106, such as a third and a fourth sub-pixel. Each sub-pixel 106 has an OLED material 112 configured to emit a white, red, green, blue or other color light when energized. E.g., the OLED material 112 of the first sub-pixel 108a emits a red light when energized, the OLED material of the second sub-pixel 108b emits a green light when energized, the OLED material of a third sub-pixel emits a blue light when energized, and the OLED material of a fourth sub-pixel emits a other color light when energized.

The inorganic silicon-containing overhang structures 110 are disposed on an upper surface 103 of each of the PDL structures 126 in the first configuration and the second configuration, as shown in FIGS. 1A and 1B. The inorganic silicon-containing overhang structures 110 are disposed on the assistant cathode 128 in the third configuration and the fourth configuration, as shown in FIGS. 1C and 1D. The assistant cathode 128 is disposed on the upper surface 103 of the PDL structures 126. The inorganic silicon-containing overhang structures 110 are permanent to the sub-pixel circuit 100. The inorganic silicon-containing overhang structures 110 further define each sub-pixel 106 of the sub-pixel circuit 100.

A first configuration (shown in FIG. 1A) and a third configuration (shown in FIG. 1C) of the inorganic silicon-containing overhang structures 110 includes a gradient concentration profile 130. The inorganic silicon-containing overhang structures 110 having the gradient concentration profile 130 may be formed by the method 300, as described herein. The first configuration (shown in FIG. 1A) of the inorganic silicon-containing overhang structures 110 includes at least the gradient concentration profile 130. The third configuration (shown in FIG. 1C) of the inorganic silicon-containing overhang structures 110 includes at least the gradient concentration profile 130 and the assistant cathode 128 disposed under the inorganic silicon-containing overhang structures 110.

The inorganic silicon-containing overhang structures 110 having the gradient concentration profile 130 include sidewalls 132, a top surface 134, and a bottom surface 136. At least the top surface 134 is wider than the bottom surface 136 of the inorganic silicon-containing overhang structures 110 to form an overhang 109. The top surface 134 larger than the bottom surface 136 forming the overhang 109 allows for shadowing. As shown in FIG. 1A, the inorganic silicon-containing overhang structures 110 having the gradient concentration profile 130 include the sidewalls 132 having a curved profile. As shown in FIG. 1C, the inorganic silicon-containing overhang structures 110 having the gradient concentration profile 130 include the sidewalls 132 having an angled profile. Although the first configuration is shown with the sidewalls 132 having the curved profile and the second configuration is shown with the sidewalls 132 having the angled profile, the first configuration and the third configuration may include the sidewalls 132 with either the angled profile or the curved profile. The sidewalls 132 are not limited to the profiles shown herein and may be any suitable profile.

The silicon-containing material of the inorganic silicon-containing overhang structures 110 includes oxides or nitrides of silicon, or combinations thereof. The gradient concentration profile 130 is defined by the silicon-containing material having an oxygen concentration and a nitrogen concentration throughout a thickness 138 of inorganic silicon-containing overhang structures 110. The thickness 138 is between about 0.5 μm to about 3 μm. In one embodiment, which can be combined with other embodiments described herein, the oxygen concentration decreases and the nitrogen concentration increases from the bottom surface 136 to the top surface 134. In another embodiment, which can be combined with other embodiments described herein, the oxygen concentration increases and the nitrogen concentration decreases from the bottom surface 136 to the top surface 134.

A second configuration (shown in FIG. 1B) and a fourth configuration (shown in FIG. 1D) of the inorganic silicon-containing overhang structures 110 includes at least an upper portion 110B and a lower portion 110A. The inorganic silicon-containing overhang structures 110 having the upper portion 110B and the lower portion 110A may be formed by the method 500, as described herein. The second configuration (shown in FIG. 1B) of the inorganic silicon-containing overhang structures 110 includes at least the upper portion 1106 disposed on the lower portion 110A. The fourth configuration (shown in FIG. 1D) of the inorganic silicon-containing overhang structures 110 includes at least the upper portion 110B, the lower portion 110A, and the assistant cathode 128 disposed under the lower portion 110A.

The lower portion 110A is at least one of a silicon oxide layer, a silicon nitride layer, or a silicon oxy-nitride layer. The upper portion 110B is at least one of the silicon oxide layer, the silicon nitride layer, or the silicon oxy-nitride layer. The lower portion 110A and the upper portion 110B are different materials. At least a bottom surface 107 of the upper portion 110B is wider than a top surface 105 of the lower portion 110A to form an overhang 109. The bottom surface 107 larger than the top surface 105 forming the overhang 109 allows for the upper portion 110B to shadow the lower portion 110A.

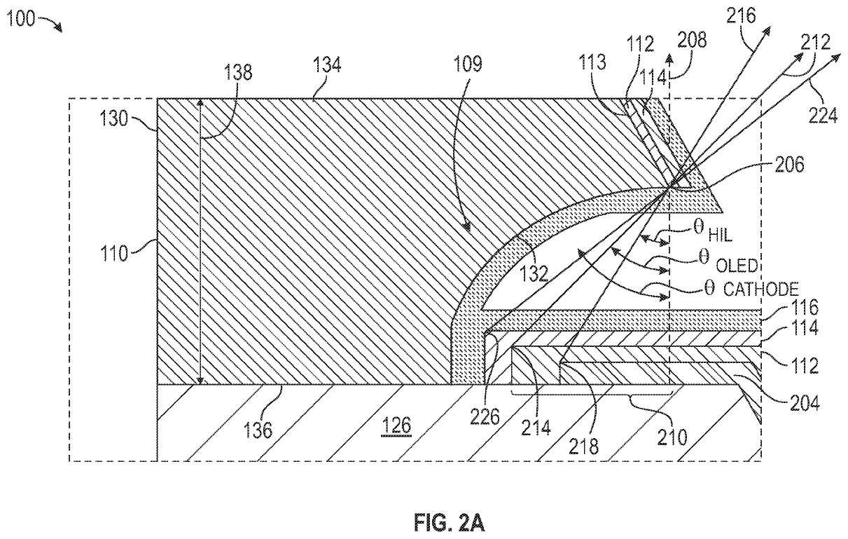

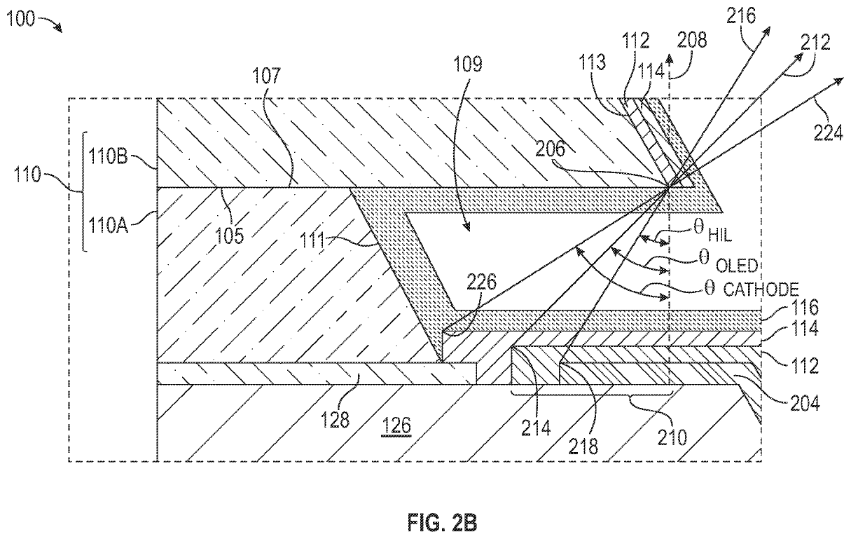

In the first, second, third, and fourth configurations of the sub-pixel circuit 100, the shadowing of the overhang 109 provides for evaporation deposition of the OLED material 112 and a cathode 114. As further discussed in the corresponding description of FIGS. 2A and 2B, the shadowing effect of the inorganic silicon-containing overhang structures 110 define a OLED angle θ_{OLED} (shown in FIGS. 2A and 2B) of the OLED material 112 and a cathode angle θ_{cathode} (shown in FIGS. 2A and 2B) of the cathode 114. The OLED angle θ_{OLED} of the OLED material 112 and the cathode angle θ_{cathode} of the cathode 114 may result from evaporation deposition of the OLED material 112 and the cathode 114.

In the first and second configurations, as shown in FIGS. 1A and 1C, the OLED material 112 does not contact the inorganic silicon-containing overhang structures 110 and the cathode 114 contacts the inorganic silicon-containing overhang structures 110. In the third and fourth configurations, as shown in FIGS. 1B and 1D, the OLED material 112 does not contact the assistant cathode 128, and the cathode 114 contacts at least the assistant cathode 128. In some configurations the cathode 114 contacts busbars (not shown) outside of an active area of the sub-pixel circuit 100.

The OLED material 112 may include one or more of a HIL, a HTL, an EML, and an ETL. The OLED material 112 is disposed on the metal layer 104. In some embodiments, which can be combined with other embodiments described herein, the OLED material 112 is disposed on the metal layer 104 and over a portion of the PDL structures 126. The cathode 114 is disposed over the OLED material 112 of the PDL structures 126 in each sub-pixel 106. The cathode 114 and the assistant cathode 128 include a conductive material, such as a metal. E.g., the cathode 114 and/or the assistant cathode 128 include, but are not limited to, chromium, titanium, aluminum, ITO, or a combination thereof.

In some embodiments, which can be combined with other embodiments described herein, the OLED material 112 and the cathode 114 are disposed over sidewalls 113 of the upper portion 110B of the inorganic silicon-containing overhang structures 110 (shown in FIGS. 1B and 1D). In other embodiments, which can be combined with other embodiments described herein, the OLED material 112 and the cathode 114 are disposed over a top surface 115 of the upper portion 110B of the inorganic silicon-containing overhang structures 110 (shown in FIGS. 1B and 1D). In other embodiments, which can be combined with other embodiments described herein, the OLED material 112 and the cathode 114 are disposed over the top surface 134 of the inorganic silicon-containing overhang structures 110 (shown in FIGS. 1A and 1C).

Each sub-pixel 106 includes include an encapsulation layer 116. The encapsulation layer 116 may be or may correspond to a local passivation layer. The encapsulation layer 116 of a respective sub-pixel is disposed over the cathode 114 (and OLED material 112) with the encapsulation layer 116 extending under at least a portion of of the overhang 109 and along the sidewalls 111 of the lower portion 110A or the sidewalls 132 of the inorganic silicon-containing overhang structures 110. In some embodiments, which can be combined with other embodiments described herein, the encapsulation layer 116 is disposed over the sidewall 113 of the upper portion 110B (shown in FIG. 1B and 1B). In some embodiments, which can be combined with other embodiments described herein, the encapsulation layer 116 is disposed over at least a portion of the top surface 115 of the upper portion 110B or the top surface 134 of the inorganic silicon-containing overhang structures 110 (shown in FIGS. 1A-1D). The encapsulation layer 116 includes a non-conductive inorganic material, such as the silicon-containing material. For example, the encapsulation layer 116 includes Si₃N₄ containing materials.

In embodiments including one or more capping layers, the capping layers are disposed between the cathode 114 and the encapsulation layer 116. E.g., as shown in FIGS. 1C and 1D, a first capping layer 121 and a second capping layer 123 are disposed between the cathode 114 and the encapsulation layer 116. While FIGS. 1C and 1D depict the sub-pixel circuit 100 having one or more capping layers, each of the embodiments described herein may include one or more capping layers disposed between the cathode 114 and the encapsulation layer 116. The first capping layer 121 may include an organic material. The second capping layer 123 may include an inorganic material, such as lithium fluoride. The first capping layer 121 and the second capping layer 123 may be deposited by evaporation deposition.

The plugless arrangement 101B and the plug arrangement 101A of the sub-pixel circuit 100 further include at least a global passivation layer 120 disposed over the inorganic silicon-containing overhang structures 110 and the encapsulation layers 116. An inkjet layer 118 may be disposed between the global passivation layer 120 and the inorganic silicon-containing overhang structures 110 and the encapsulation layers 116. The inkjet layer 118 may include an acrylic material. The plug arrangement 101A (including the third and fourth exemplary embodiments) may include an intermediate passivation layer (not shown) disposed over the inorganic silicon-containing overhang structures 110 and plugs 122 of each of the sub-pixels 106, and disposed between the inkjet layer 118 and the global passivation layer 120.

The plug arrangement 101A, including the third and fourth exemplary embodiments, includes the plugs 122 disposed over the encapsulation layers 116. Each plug 122 is disposed in a respective sub-pixel 106 of the sub-pixel circuit 100. The plugs 122 may be disposed over the top surface 115 of the upper portion 1106 or the top surface 134 of the inorganic silicon-containing overhang structures 110. The plugs 122 may have an additional passivation layer (not shown) disposed thereon. The plugs 122 include, but are not limited to, a photoresist, a color filter, or a photosensitive monomer. The plugs 122 have a plug transmittance that is matched or substantially matched to an OLED transmittance of the OLED material 112. The plugs 122 may each be the same material and match the OLED transmittance. The plugs 122 may be different materials that match the OLED transmittance of each respective sub-pixel of the plurality of sub-pixels 106. The matched or substantially matched resist transmittance and OLED transmittance allow for the plugs 122 to remain over the sub-pixels 106 without blocking the emitted light from the OLED material 112. The plugs 122 are able to remain in place and thus do not require a lift off procedure to be removed from the sub-pixel circuit 100. Additional pattern resist materials disposed over the formed sub-pixels 106 at subsequent operations are not required because the plugs 122 remain. Eliminating the need for a lift-off procedure on the plugs 122 and the need for additional pattern resist materials on the sub-pixel circuit 100 increases throughput.

The first, second, third, and fourth exemplary embodiments of the sub-pixel circuit 100 include inorganic silicon-containing overhang structures 110 of at least one of the first, second, third, or fourth configurations. The inorganic silicon-containing overhang structures 110 are able to remain in place, i.e., are permanent. Thus, organic material from lifted off overhang structures that disrupt OLED performance would not be left behind. Eliminating the need for a lift-off procedure also increases throughput.

FIG. 1E is a schematic, top sectional view of a sub-pixel circuit 100 having a dot-type architecture 101C. The dot-type architecture 101C may correspond to the first or third exemplary embodiments of the sub-pixel circuit 100. The dot-type architecture 101C includes a plurality of pixel openings 124A. Each of pixel opening 124A is surrounded by inorganic silicon-containing overhang structures 110 that define each of the sub-pixels 106 of the dot-type architecture 101C. Each of the top sectional views of FIG. 1E are taken along section line 1′-1′ of FIGS. 1A-1D.

FIG. 1F is a schematic, cross-sectional view of a sub-pixel circuit 100 having a line-type architecture 101D. The line-type architecture 101D may correspond to the second or fourth exemplary embodiments of the sub-pixel circuit 100. The line-type architecture 101D includes a plurality of pixel openings 124B. Each of pixel opening 124B is abutted by inorganic silicon-containing overhang structures 110 that define each of the sub-pixels 106 of the line-type architecture 101D. Each of the top sectional views of FIG. 1F are taken along section line 1′-1′ of FIGS. 1A-1D.

Each of a method 300 and a method 500 of fabricating a sub-pixel circuit 100 with the inorganic silicon-containing overhang structures 110 described herein provide for the ability to fabricate both the sub-pixel circuit 100 with the dot-type architecture 101C and the sub-pixel circuit 100 with the line-type architecture 101D.

FIG. 2A and FIG. 2B are schematic, cross-sectional views of an inorganic silicon-containing overhang structure 110 according to embodiments. While FIG. 2A depicts the first configuration (shown in FIG. 1A) of the inorganic silicon-containing overhang structures 110, the description herein is applicable to the third configuration (shown in FIG. 1C) of the inorganic silicon-containing overhang structures 110 including the assistant cathode 128. Although the inorganic silicon-containing overhang structure 110 includes a sidewall 132 having a curved profile, the description herein is applicable to the sidewall 132 having an angled profile (shown in FIG. 1C).

The sidewall 132 and the top surface 134 define an underside edge 206. The inorganic silicon-containing overhang structure 110 includes an overhang vector 208. The overhang vector 208 is defined by the underside edge 206 and the PDL structure 126. The OLED material 112 is disposed over the anode and over a shadow portion 210 of the PDL structure 126. The OLED material 112 forms an OLED angle eoLED between an OLED vector 212 and the overhang vector 208. The OLED vector 212 is defined by an OLED edge 214 extending under the underside edge 206. In one embodiment, which can be combined with other embodiments described herein, a HIL 204 of the OLED material 112 is included. In the embodiment including the HIL 204, the OLED material 112 includes the HTL, the EML, and the ETL. The HIL 204 forms an HIL angle OHL between a HIL vector 216 and the overhang vector 208. The HIL vector 216 is defined by an HIL edge 218 extending under the underside edge 206.

FIG. 2A shows the cathode 114 disposed over the OLED material 112 and over the shadow portion 210 of the PDL structure 126. As shown in FIG. 2A, the cathode 114 does not contact the sidewall 132 of the inorganic silicon-containing overhang structure 110. In embodiments including the third configuration, the cathode 114 does not contact the sidewall 132 of the inorganic silicon-containing overhang structure 110 or the assistant cathode 128. In other embodiments, which can be combined with other embodiments described herein, the cathode 114 may contact the sidewall 132 of the inorganic silicon-containing overhang structure 110. In embodiments including the third configuration of the inorganic silicon-containing overhang structure 110, the cathode 114 contacts at least the assistant cathode 128 and may also contact the sidewall 132 of the inorganic silicon-containing overhang structure 110. The cathode 114 may also contact the assistant cathode 128 in the third configuration. The cathode 114 forms a cathode angle ecathode between a cathode vector 224 and the overhang vector 208. The cathode vector 224 is defined by a cathode edge 226 at least extending under underside edge 206. The encapsulation layer 116 is disposed over the cathode 114 (and OLED material 112) with the encapsulation layer 116 extending at least along the sidewall 132 of the inorganic silicon-containing overhang structure 110.

During evaporation deposition of the OLED material 112, the underside edge 206 defines the position of the OLED edge 214. E.g., the OLED material 112 is evaporated at an OLED maximum angle that corresponds to the OLED vector 212 and the underside edge 206 ensures that the OLED material 112 is not deposited past the OLED edge 214. In embodiments with the HIL 204, the underside edge 206 defines the position of the HIL edge 218. E.g., the HIL 204 is evaporated at an HIL maximum angle that corresponds to the HIL vector 216 and the underside edge 206 ensures that HIL 204 is not deposited past the HIL edge 218. During evaporation deposition of the cathode 114, the underside edge 206 defines the position of the cathode edge 226. E.g., the cathode 114 is evaporated at a cathode maximum angle that corresponds to the cathode vector 224 and the underside edge 206 ensures that the cathode 114 is not deposited past the cathode edge 226. The OLED angle θ_{OLED} is less than the cathode angle θ_{cathode}. The HIL angle θ_{HIL} is less than the OLED angle θ_{OLED}.

While FIG. 2B depicts the fourth configuration (shown in FIG. 1D) of the inorganic silicon-containing overhang structures 110, the description herein is applicable to the second configuration (shown in FIG. 1B) of the inorganic silicon-containing overhang structures 110.

The upper portion 110B includes an underside edge 206 and an overhang vector 208. The underside edge 206 extends past the sidewall 111 of the lower portion 110A. The overhang vector 208 is defined by the underside edge 206 and the PDL structure 126. The OLED material 112 is disposed over the anode and over a shadow portion 210 of the PDL structure 126. The OLED material 112 forms an OLED angle θ_{OLED} between an OLED vector 212 and the overhang vector 208. The OLED vector 212 is defined by an OLED edge 214 extending under the upper portion 110B and the underside edge 206 of the upper portion 110B. In one embodiment, which can be combined with other embodiments described herein, a HIL 204 of the OLED material 112 included. In the embodiment including the HIL 204, the OLED material 112 includes the HTL, the EML, and the ETL. The HIL 204 forms an HIL angle θ_{HIL} between a HIL vector 216 and the overhang vector 208. The HIL vector 216 is defined by an HIL edge 218 extending under the upper portion 110B and the underside edge 206 of the upper portion 110B.

FIG. 2B shows the cathode 114 disposed over the OLED material 112 and over the shadow portion 210 of the PDL structure 126. As shown in FIG. 2B, the cathode 114 contacts at least the assistant cathode 128. The cathode 114 may contact the assistant cathode 128 and the lower portion 110A of the inorganic silicon-containing overhang structure 110. In embodiments including the second configuration of the inorganic silicon-containing overhang structure 110, the cathode 114 contacts the lower portion 110A of the inorganic silicon-containing overhang structure 110. In other embodiments, which can be combined with other embodiments described herein, the cathode 114 does not contact the inorganic silicon-containing overhang structure 110 or the assistant cathode 128.

The cathode 114 forms a cathode angle θ_{cathode} between a cathode vector 224 and the overhang vector 208. The cathode vector 224 is defined by a cathode edge 226 at least extending under the upper portion 110B and the underside edge 206 of the upper portion 110B. The encapsulation layer 116 is disposed over the cathode 114 (and OLED material 112) with the encapsulation layer 116 extending at least under the upper portion 110B of the inorganic silicon-containing overhang structure 110 and along the sidewall 111 of the lower portion 110A.

During evaporation deposition of the OLED material 112, the underside edge 206 of the upper portion 110B defines the position of the OLED edge 214. E.g., the OLED material 112 is evaporated at an OLED maximum angle that corresponds to the OLED vector 212 and the underside edge 206 ensures that the OLED material 112 is not deposited past the OLED edge 214. In embodiments with the HIL 204, the underside edge 206 of the upper portion 110B defines the position of the HIL edge 218. E.g., the HIL 204 is evaporated at an HIL maximum angle that corresponds to the HIL vector 216 and the underside edge 206 ensures that HIL 204 is not deposited past the HIL edge 218. During evaporation deposition of the cathode 114, the underside edge 206 of the upper portion 110B defines the position of the cathode edge 226. E.g., the cathode 114 is evaporated at a cathode maximum angle that corresponds to the cathode vector 224 and the underside edge 206 ensures that the cathode 114 is not deposited past the cathode edge 226. The OLED angle θ_{OLED} is less than the cathode angle θ_{cathode}. The HIL angle θ_{HIL} is less than the OLED angle θ_{OLED}.

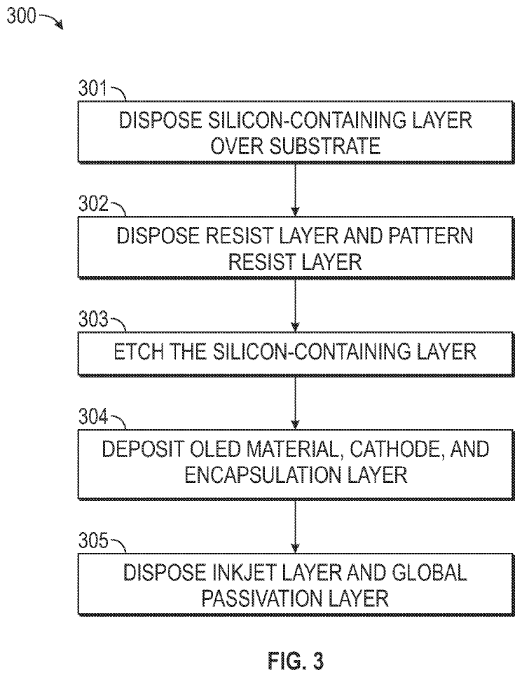

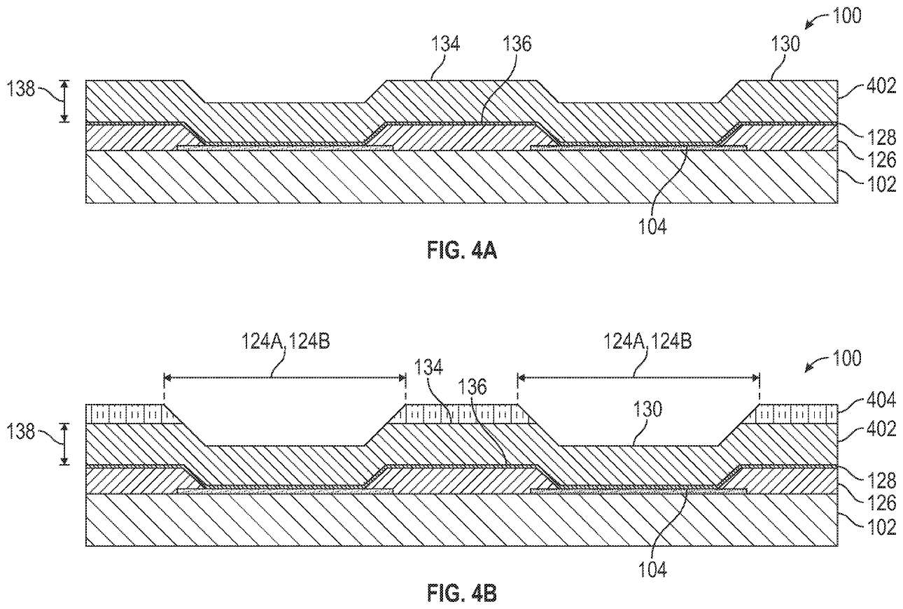

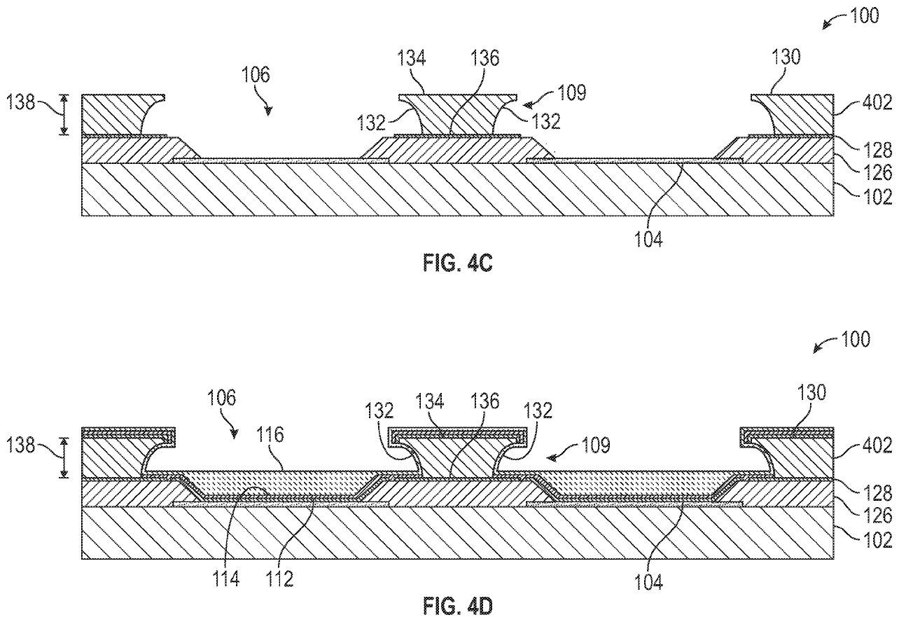

FIG. 3 is a flow a flow diagram of a method 300 for fabricating a sub-pixel circuit 100 with inorganic silicon-containing overhang structures 110 having a gradient concentration profile 130. The method 300 is operable to fabricate a sub-pixel circuit 100 of one of the first, second, third, or fourth exemplary embodiments. FIGS. 4A-4D are schematic, cross-sectional views of a substrate 102 during the method 300 for forming the sub-pixel circuit 100 according to embodiments described herein. The method 300 corresponds to a fifth exemplary embodiment of the embodiments described herein to fabricate overhang structures with a gradient concentration profile of one of the first, second, third, or fourth exemplary embodiments. While the method 300 shown in FIGS. 4A-4D corresponds to fabricating the third configuration (shown in FIG. 1C) of the inorganic silicon-containing overhang structures 110, the method 300 is also applicable to forming the first configuration (shown in FIG. 1A) of the inorganic silicon-containing overhang structures 110. While FIGS. 4C and 4D show sidewalls 132 of the inorganic silicon-containing overhang structures 110 having a curved profile, the sidewalls 132 may have an angled profile.

At operation 301, as shown in FIG. 4A, a silicon-containing layer 402 is disposed over a substrate 102. The silicon-containing layer 402 is disposed over PDL structures 126 and metal layers 104. The silicon-containing layer 402 corresponds to the inorganic silicon-containing overhang structures 110 to be formed having the gradient concentration profile 130. In embodiments including the third configuration of the inorganic silicon-containing overhang structures 110, an assistant cathode 128 is disposed between the silicon-containing layer 402 and the PDL structures 126 and the metal layers 104. The silicon-containing layer 402 has an oxygen concentration and a nitrogen concentration across a thickness 138 of the silicon-containing layer 402 that defines the gradient concentration profile 130. In one embodiment, which can be combined with other embodiments described herein, the oxygen concentration decreases and the nitrogen concentration increases across the thickness 138 from a bottom surface 136 to a top surface 134 of the silicon-containing layer 402. In another embodiment, which can be combined with other embodiments described herein, the oxygen concentration increases and the nitrogen concentration decreases across the thickness 138 from the bottom surface 136 to the top surface 134 of the silicon-containing layer 402.

At operation 302, as shown in FIG. 4B, a resist layer 404 is disposed and patterned. The resist layer 404 is disposed over the silicon-containing layer 402. The resist layer 404 is a positive resist or a negative resist. A positive resist includes portions of the resist, which, when exposed to electromagnetic radiation, are respectively soluble to a resist developer applied to the resist after the pattern is written into the resist using the electromagnetic radiation. A negative resist includes portions of the resist, which, when exposed to radiation, will be respectively insoluble to the resist developer applied to the resist after the pattern is written into the resist using the electromagnetic radiation. The chemical composition of the resist layer 404 determines whether the resist is a positive resist or a negative resist. The resist layer 404 is patterned to form one of a pixel opening 124A of the dot-type architecture 101C or a pixel opening 124B of the line-type architecture 101D of a sub-pixel 106. The patterning is one of a photolithography, digital lithography process, or laser ablation process.

At operation 303, as shown in FIG. 4C, the silicon-containing layer 402 is etched. Portions of the silicon-containing layer 402 exposed by the pixel opening 124A, 124B are removed with an etch process. Operation 303 forms the inorganic silicon-containing overhang structures 110 from the silicon-containing layer 402 of the sub-pixels 106. The etch chemistry of the etch process of operation 303 includes a wet etch chemistry, a dry etch chemistry, or combinations thereof. In one embodiment, which can be combined with other embodiments described herein, the wet etch chemistry includes, but is not limited to, buffered hydrofluoric acid (BHF), buffer oxide etchant (BOE), or combinations thereof. In another embodiment, which can be combined with other embodiments described herein, the dry etch chemistry includes, but is not limited to, carbon tetrafluoride (CF₄), oxygen, nitrogen, hydrogen, nitrogen trifluoride (NF₃), sulfer hexafluoride (SF₆), fluroform (CHF₃), or combinations thereof. In embodiments including the assistant cathode 128, a portion of the assistant cathode 128 may be removed by a dry etch process or a wet etch process to form the assistant cathode 128 disposed under the inorganic silicon-containing overhang structures 110.

To form the sidewalls 132 of the inorganic silicon-containing overhang structure 110, the etch chemistry is selected based on the gradient concentration profile 130 of the silicon-containing layer 402. The etch chemistry will etch the silicon-containing layer 402 at different rates across the thickness 138 of the silicon-containing layer 402. In one example, the oxygen concentration decreases and the nitrogen concentration increases in the silicon-containing layer 402 from the bottom surface 136 to the top surface 134 of the inorganic silicon-containing overhang structures 110. Therefore, the etch chemistry will etch portions of the silicon-containing layer 402 with a greater oxygen concentration than nitrogen concentration closer to the bottom surface 136 faster than portions of the silicon-containing layer 402 with a greater nitrogen concentration than oxygen concentration closer to the top surface 134. In another example, the oxygen concentration increases and the nitrogen concentration decreases in the silicon-containing layer 402 from the bottom surface 136 to the top surface 134 of the inorganic silicon-containing overhang structures 110. Therefore, the etch chemistry will etch portions of the silicon-containing layer 402 with a greater nitrogen concentration than oxygen concentration closer to the bottom surface 136 faster than portions of the silicon-containing layer 402 with a greater oxygen concentration than nitrogen concentration closer to the top surface 134. The top surface 134 being wider than the bottom surface 136 forms an overhang 109 (as shown in FIGS. 1A, 1C, and 2A). The shadowing of the overhang 109 provides for evaporation deposition of OLED material 112 and a cathode 114.

In one embodiment, which can be combined with other embodiments descried herein, the etch selectivity of the dry etch chemistry provides for a selectivity of silicon oxide (SiOx) to silicon oxynitride (SiON) of about 1:1.5, a selectivity of silicon oxide (SiOx) to silicon nitride (SiNx) of about 1:2, and a selectivity of silicon oxynitride (SiON) to silicon nitride (SiNx) of about 1.5:2. In another embodiment, which can be combined with other embodiments described herein, the etch selectivity of the wet etch chemistry provides for a selectivity of silicon oxide (SiOx) to silicon oxynitride (SiON) of about 2:1.5, a selectivity of silicon oxide (SiOx) to silicon nitride (SiNx) of about 2:1, and a selectivity of silicon oxynitride (SiON) to silicon nitride (SiNx) of about 1.5:1. In yet another embodiment, which can be combined with other embodiments described herein, the etch selectivity can be adjusted by using a combination of the wet etch and dry etch chemistries.

At operation 304, as shown in FIG. 4D, the OLED material 112, the cathode 114, and the encapsulation layer 116 are disposed. The shadowing of the overhang 109 provides for evaporation deposition each of the OLED material 112 and the cathode 114. As further discussed in the corresponding description of FIG. 2A, the shadowing effect of the inorganic silicon-containing overhang structures 110 define the OLED angle θ_{OLED} (shown in FIG. 2A) of the OLED material 112 and the cathode angle θ_{cathode} (shown in FIG. 2A) of the cathode 114. The OLED angle θ_{OLED} of the OLED material 112 and the cathode angle θ_{cathode} of the cathode 114 result from evaporation deposition of the OLED material 112 and the cathode 114. In the first configuration, the OLED material 112 does not contact and the cathode 114 contacts the inorganic silicon-containing overhang structures 110. In the third configuration, the OLED material 112 the assistant cathode 128, and the cathode 114 contacts at least the assistant cathode 128. The encapsulation layer 116 is deposited over the cathode 114. In embodiments including capping layers, the capping layers are deposited between the cathode 114 and the encapsulation layer 116. The capping layers may be deposited by evaporation deposition.

At operation 305, as shown in FIGS. 1A and 1C, the inkjet layer 118 and the global passivation layer 120 are disposed. In the third and fourth exemplary embodiments of the sub-pixel circuit 100 having a plug arrangement 101A, plugs 122 are disposed over the encapsulation layers 116.

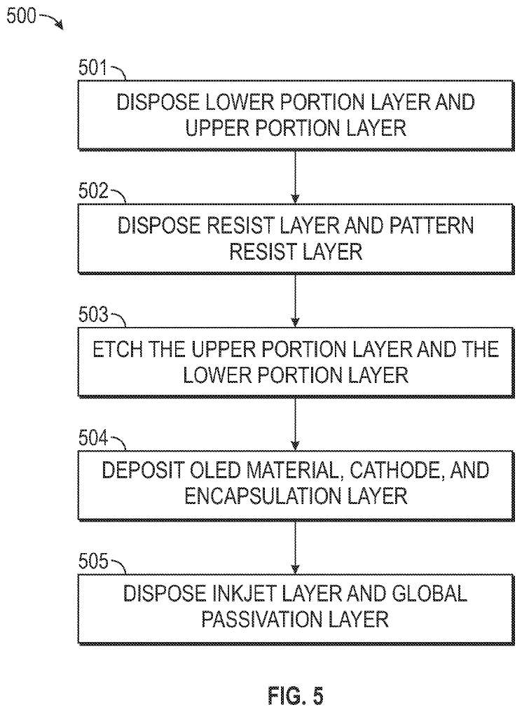

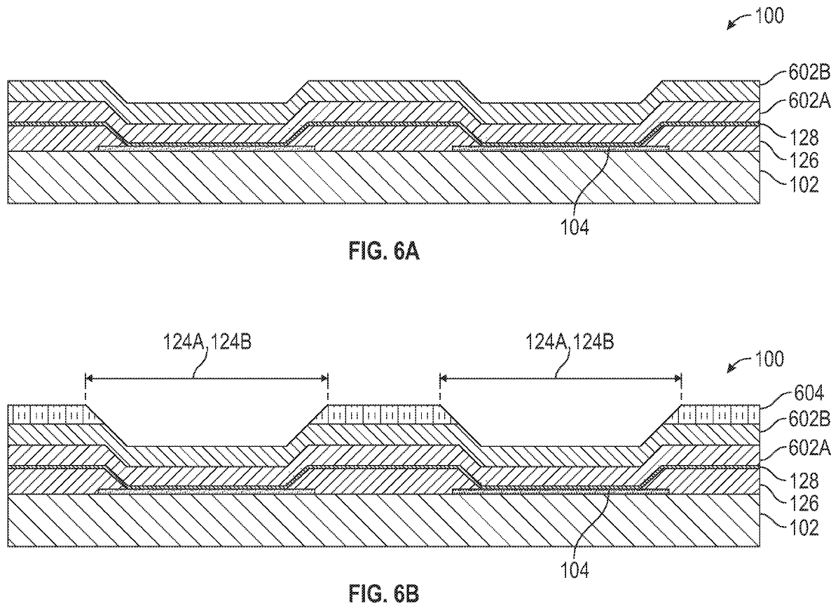

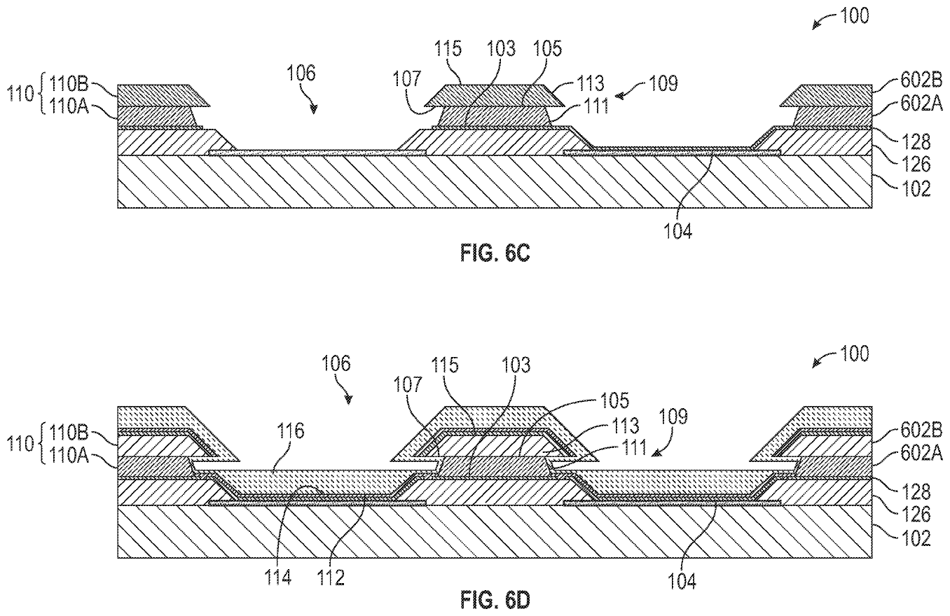

FIG. 5 is a flow diagram of a method 500 for fabricating a sub-pixel circuit 100 with inorganic silicon-containing overhang structures 110 including an upper portion 110B and a lower portion 110A. The method 500 is operable to fabricate a sub-pixel circuit 100 of one of the first, second, third, or fourth exemplary embodiments. FIGS. 6A-6D are schematic, cross-sectional views of a substrate 102 during the method 500 for forming the sub-pixel circuit 100 according embodiments described herein. The method 500 corresponds to a sixth exemplary embodiment of the embodiments described herein to fabricate inorganic silicon-containing overhang structures with the upper portion 110B and the lower portion 110A of one of the first, second, third, or fourth exemplary embodiments. While the method 500 shown in FIGS. 6A-6D corresponds to fabricating the fourth configuration (shown in FIG. 1D) of the inorganic silicon-containing overhang structures 110, the method 500 is also applicable to forming the second configuration (shown in FIG. 1B) of the inorganic silicon-containing overhang structures 110.

At operation 501, as shown in FIG. 6A, a lower portion layer 602A and an upper portion layer 602B are disposed over the substrate 102. The lower portion layer 602A is disposed over the PDL structures 126 and the metal layers 104. The upper portion layer 602B is disposed over the lower portion layer 602A. The lower portion layer 602A corresponds to the lower portion 110A and the upper portion layer 602B corresponds to the upper portion 110B of the inorganic silicon-containing overhang structures 110. In embodiments including fourth configuration of the inorganic silicon-containing overhang structures 110, an assistant cathode 128 is disposed between the lower portion layer 602A and the PDL structures 126 and the metal layers 104. The lower portion layer 602A is at least one of a silicon oxide layer, a silicon nitride layer, or a silicon oxy-nitride layer. The upper portion layer 602B is at least one of the silicon oxide layer, the silicon nitride layer, or the silicon oxy-nitride layer.

At operation 502, as shown in FIG. 6B, a resist 604 is disposed and patterned. The resist 604 is disposed over the upper portion layer 602B. The resist 604 is a positive resist or a negative resist. The chemical composition of the resist 604 determines whether the resist is a positive resist or a negative resist. The resist 604 is patterned to form one of a pixel opening 124A of the dot-type architecture 101C or a pixel opening 124B of the line-type architecture 101D of a sub-pixel 106. The patterning is one of a photolithography, digital lithography process, or laser ablation process.

At operation 503, as shown in FIG. 6C, portions of the upper portion layer 602B and the lower portion layer 602A are etched. The portions of the upper portion layer 604B and the lower portion layer 602A exposed by the pixel opening 124A, 124B are removed with an etch process. Operation 503 forms the inorganic silicon-containing overhang structures 110 of the sub-pixel 106. The etch chemistry of the etch process of operation 303 includes a wet etch chemistry, a dry etch chemistry, or combinations thereof. In one embodiment, which can be combined with other embodiments described herein, the wet etch chemistry includes, but is not limited to, buffered hydrofluoric acid (BHF), buffer oxide etchant (BOE), or combinations thereof. In another embodiment, which can be combined with other embodiments described herein, the dry etch chemistry includes, but is not limited to, carbon tetrafluoride (CF₄), oxygen, nitrogen, hydrogen, nitrogen trifluoride (NF₃), sulfer hexafluoride (SF₆), fluroform (CHF₃), or combinations thereof. In embodiments including the assistant cathode 128, a portion of the assistant cathode 128 may be removed by a dry etch process or a wet etch process to form the assistant cathode 128 disposed under the inorganic silicon-containing overhang structures 110.

To form the lower portion 110A and the upper portion 110B of the inorganic silicon-containing overhang structures 110, the etch chemistry is selected based on the composition of the upper portion layer 602B and the lower portion layer 602A. The etch selectivity between the materials of the upper portion layer 602B and the lower portion layer 602A and the etch processes to remove the exposed portions of the upper portion layer 602B and the lower portion layer 602A provide for a bottom surface 107 of the upper portion 110B being wider than a top surface 105 of the lower portion 110A to form the overhang 109 (as shown in FIGS. 1B, 1D, and 2B). The shadowing of the overhang 109 provides for evaporation deposition the OLED material 112 and the cathode 114. In one example, the lower portion layer 602A is a silicon oxide layer or a silicon oxynitride layer and the upper portion layer 602B is a silicon nitride layer. Therefore, the etch chemistry will etch the lower portion layer 602A faster than the upper portion layer 602B. In another example, the lower portion layer 602A is a silicon nitride layer and the upper portion layer 602B is a silicon oxide layer or a silicon oxynitride layer. Therefore, the etch chemistry will etch the lower portion layer 602A faster than the upper portion layer 602B.

In one embodiment, which can be combined with other embodiments descried herein, the etch selectivity of the dry etch chemistry provides for a selectivity of silicon oxide (SiOx) to silicon oxynitride (SiON) of about 1:1.5, a selectivity of silicon oxide (SiOx) to silicon nitride (SiNx) of about 1:2, and a selectivity of silicon oxynitride (SiON) to silicon nitride (SiNx) of about 1.5:2. In another embodiment, which can be combined with other embodiments described herein, the etch selectivity of the wet etch chemistry provides for a selectivity of silicon oxide (SiOx) to silicon oxynitride (SiON) of about 2:1.5, a selectivity of silicon oxide (SiOx) to silicon nitride (SiNx) of about 2:1, and a selectivity of silicon oxynitride (SiON) to silicon nitride (SiNx) of about 1.5:1. In yet another embodiment, which can be combined with other embodiments described herein, the etch selectivity can be adjusted by using a combination of the wet etch and dry etch chemistries.

At operation 504, as shown in FIG. 6D, the OLED material 112, the cathode 114, and the encapsulation layer 116 are deposited. The shadowing of the overhang 109 provides for evaporation deposition each of the OLED material 112 and the cathode 114. As further discussed in the corresponding description of FIG. 2B, the shadowing effect of the inorganic silicon-containing overhang structures 110 define the OLED angle θ_{OLED} (shown in FIG. 2B) of the OLED material 112 and the cathode angle θ_{cathode} (shown in FIG. 2B) of the cathode 114. The OLED angle θ_{OLED} of the OLED material 112 and the cathode angle θ_{cathode} of the cathode 114 result from evaporation deposition of the OLED material 112 and the cathode 114. In the second configuration, the OLED material 112 does not contact and the cathode 114 contacts the lower portion 110A of the inorganic silicon-containing overhang structures 110. In the fourth configuration, the OLED material 112 does not contact the lower portion 110A and the assistant cathode 202, and the cathode 114 contacts at least the assistant cathode 128. The encapsulation layer 116 is deposited over the cathode 114. In embodiments including capping layers, the capping layers are deposited between the cathode 114 and the encapsulation layer 116. The capping layers may be deposited by evaporation deposition.

At operation 505, as shown in FIGS. 1B and 1D, the inkjet layer 118 and the global passivation layer 120 are disposed. In the third and fourth exemplary embodiments of the sub-pixel circuit 100 having a plug arrangement 101A, plugs 122 are disposed over the encapsulation layers 116.

In summation, embodiments described herein relate to overhang structures and methods of fabricating a sub-pixel circuit 100 with the overhang structures that may be utilized in a display such as an organic light-emitting diode (OLED) display. The adjacent inorganic silicon-containing overhang structures defining each sub-pixel of the sub-pixel circuit of the display provide for formation of the sub-pixel circuit using evaporation deposition and provide for the inorganic silicon-containing overhang structures to remain in place after the sub-pixel circuit is formed. A first configuration of the inorganic silicon-containing overhang structures includes a gradient concentration profile. A second configuration of the inorganic silicon-containing overhang structures includes an upper portion and a lower portion. Evaporation deposition may be utilized for deposition of an OLED material and cathode. The inorganic silicon-containing overhang structures define deposition angles, i.e., provide for a shadowing effect during evaporation deposition, for each of the OLED material and the cathode such the OLED material does not contact sidewalls of the inorganic silicon-containing overhang structures (and assistant cathode according to embodiments with the third and fourth configurations). The encapsulation layer of a respective sub-pixel is disposed over the cathode with the encapsulation layer extending under at least a portion of each of the adjacent inorganic silicon-containing overhang structures.

While the foregoing is directed to embodiments of the present disclosure, other and further embodiments of the disclosure may be devised without departing from the basic scope thereof, and the scope thereof is determined by the claims that follow.

What is claimed is:

1. A device, comprising:
a substrate;
adjacent pixel-defining layer (PDL) structures disposed over the substrate and defining sub-pixels of the device;
inorganic silicon-containing overhang structures disposed over an upper surface of the PDL structures, the inorganic silicon-containing overhang structures having an oxygen concentration and a nitrogen concentration, wherein:
at least one of the oxygen concentration decreases or the nitrogen concentration increases from the upper surface of the PDL structures; or
at least one of the oxygen concentration increases or the nitrogen concentration decreases from the upper surface of the PDL structures; and
a plurality of sub-pixels, each sub-pixel comprising:
an anode;
an organic light-emitting diode (OLED) material disposed over and in contact with the anode; and
a cathode disposed over the OLED material, wherein the inorganic silicon-containing overhang structures disposed over the upper surface of the PDL structure extend over a portion of the OLED material and the cathode.

2. The device of claim 1, wherein sidewalls of the inorganic silicon-containing overhang structures have a curved profile or an angled profile.

3. The device of claim 1, wherein an assistant cathode is disposed under the inorganic silicon-containing overhang structures.

4. A device, comprising:
a substrate;
adjacent pixel-defining layer (PDL) structures disposed over the substrate and defining sub-pixels of the device;
inorganic silicon-containing overhang structures disposed over an upper surface of the PDL structures, the inorganic silicon-containing overhang structures having:
a lower portion, the lower portion having a first composition of at least one of a silicon oxide, a silicon nitride, or a silicon oxy-nitride; and
an upper portion disposed on the lower portion, the upper portion including an underside edge extending past a sidewall of the lower portion, the upper portion is at least one of the silicon oxide, the silicon nitride, or the silicon oxy-nitride, wherein the lower portion and the upper portion are different; and
a plurality of sub-pixels, each sub-pixel comprising:
an anode;
an organic light-emitting diode (OLED) material disposed over and in contact with the anode; and
a cathode disposed over the OLED material, wherein inorganic silicon-containing overhang structures disposed over the upper surface of the PDL structure extend over a portion of the OLED material and the cathode.

5. The device of claim 4, wherein the device comprises a dot-type architecture or a line-type architecture.

6. The device of claim 4, wherein an assistant cathode is disposed under the inorganic silicon-containing overhang structures.

7. A device comprising a plurality of sub-pixels, each sub-pixel of the plurality of sub-pixels defined by adjacent pixel-defining layer (PDL) structures with inorganic silicon-containing overhang structures disposed on the PDL structures, each sub-pixel having an anode, an organic light-emitting diode (OLED) material disposed on the anode, and a cathode disposed on the OLED material, wherein the device is made by a process comprising the steps of:
disposing a silicon-containing layer over an upper surface of the PDL structures, the silicon-containing layer having an oxygen concentration and a nitrogen concentration, wherein:
at least one of the oxygen concentration decreases or the nitrogen concentration increases from the upper surface of the PDL structures; or
at least one of the oxygen concentration increases or the nitrogen concentration decreases from the upper surface of the PDL structures;
disposing a resist layer over the silicon-containing layer and patterning the resist layer to form pixel openings in the resist layer;
etching the silicon-containing layer exposed by the pixel openings to form the inorganic silicon-containing overhang structures; and
depositing the OLED material and the cathode using evaporation deposition.

8. The device of claim 7, further comprising an encapsulation layer disposed over the cathode.

9. The device of claim 7, wherein sidewalls of the inorganic silicon-containing overhang structures have a curved profile or an angled profile.

10. A device comprising a plurality of sub-pixels, each sub-pixel of the plurality of sub-pixels defined by adjacent pixel-defining layer (PDL) structures with inorganic silicon-containing overhang structures disposed on the PDL structures, each sub-pixel having an anode, an organic light-emitting diode (OLED) material disposed on the anode, and a cathode disposed on the OLED material, wherein the device is made by a process comprising the steps of:
disposing a lower portion layer and an upper portion layer over an upper surface of the PDL structures, the lower portion layer including at least one of a silicon oxide, a silicon nitride, or a silicon oxy-nitride, the upper portion layer including at least one of the silicon oxide, the silicon nitride, or the silicon oxy-nitride, wherein the lower portion layer and the upper portion layer are different;
disposing a resist layer over the upper portion layer and patterning the resist layer to form pixel openings in the resist layer;
etching the upper portion layer and the lower portion layer exposed by the pixel openings to form the inorganic silicon-containing overhang structures; and
depositing the OLED material and the cathode using evaporation deposition.

11. The device of claim 10, wherein each sub-pixel further comprises a plug disposed over an encapsulation layer disposed over the cathode, the plug having a plug transmittance that is matched or substantially matched to an OLED transmittance of the OLED material.

12. The device of claim 10, wherein the device comprises a dot-type architecture or a line-type architecture.

13. A method, comprising:
disposing a silicon-containing layer over adjacent pixel defining layer (PDL) structures, each sub-pixel of a plurality of sub-pixels is defined by the adjacent PDL structures, the silicon-containing layer having an oxygen concentration and a nitrogen concentration, wherein:
the oxygen concentration decreases and the nitrogen concentration increases from an upper surface of the PDL structures; or
the oxygen concentration increases and the nitrogen concentration decreases from the upper surface of the PDL structures;
disposing a resist layer over the silicon-containing layer and patterning the resist layer to form pixel openings in the resist layer;
etching the silicon-containing layer exposed by the pixel openings to form inorganic silicon-containing overhang structures; and
depositing an organic light-emitting diode (OLED) material and a cathode using evaporation deposition.

14. The method of claim 13, further comprising disposing an encapsulation layer over the cathode.

15. The method of claim 14, further comprising disposing a global passivation layer and an inkjet layer over the inorganic silicon-containing overhang structures and the encapsulation layer.

16. The method of claim 13, wherein sidewalls of the inorganic silicon-containing overhang structures have a curved profile or an angled profile.

17. A method, comprising:
disposing a lower portion layer and an upper portion layer over adjacent pixel defining layer (PDL) structures, each sub-pixel of a plurality of sub-pixels is defined by the adjacent PDL structures, the lower portion layer including at least one of a silicon oxide, a silicon nitride, or a silicon oxy-nitride, the upper portion layer including at least one of the silicon oxide, the silicon nitride, or the silicon oxy-nitride, wherein the lower portion layer and the upper portion layer are different;
disposing a resist layer over the upper portion layer and patterning the resist layer to form pixel openings in the resist layer;
etching the upper portion layer and the lower portion layer exposed by the pixel openings to form inorganic silicon-containing overhang structures; and
depositing an organic light-emitting diode (OLED) material and a cathode using evaporation deposition.

18. The method of claim 17, wherein the etching the upper portion layer and the lower portion layer comprises one of a wet etch chemistry, a dry etch chemistry, or combinations thereof.

19. The method of claim 17, wherein the disposing the OLED material and the cathode includes evaporation deposition of the OLED material and the cathode.

20. The method of claim 17, wherein the inorganic silicon-containing overhang structures define deposition angles such that both the OLED material and the cathode are deposited by the evaporation deposition.
